(19) United States
(12) Patent Application Publication
(10) Pub. No.: US 2011/0304486 A1
(43) Pub. Date: Dec. 15, 2011

(54) SOLAR KEYBOARD AND ELECTRONIC DEVICE USING THE SAME

(76) Inventors: Huang-Hsiao Kao, Taoyuan (TW); Chun-Chung Huang, Taoyuan (TW)

(21) Appl. No.: 13/154,448

(22) Filed: Jun. 7, 2011

(30) Foreign Application Priority Data
Jun. 9, 2010 (TW) 099211010

(51) Int. Cl. H03K 17/94; H05K 7/00

(52) U.S. Cl. 341/22

(57) ABSTRACT

A solar keyboard includes a base, a touch keyboard module and a solar cell. The touch keyboard module is disposed on the base and includes a transparent layer. The solar cell is selectively disposed over or below the transparent layer. An area of the solar cell is substantially equal to that of the touch keyboard module. Accordingly, the solar keyboard of the invention can absorb much more solar energy and then generate much more electric power.

### BACKGROUND OF THE INVENTION

1. Field of the Invention

The invention relates to a solar keyboard and an electronic device using the same and, more particularly, to a solar keyboard utilizing large area to absorb much more solar energy and then convert the absorbed solar energy into electric power.

2. Description of the Prior Art

A keyboard, which is the most common input device, can be found in variety of electronic equipments for users to input characters, symbols, numerals and so on. From consumer electronic products to industrial machine tools are all equipped with a keyboard for purpose of operation.

So far some prior arts have disposed a solar cell on a keyboard so as to absorb solar energy and then convert the absorbed solar energy into electric power for purpose of operation. However, since the conventional solar keyboard only dispose a solar cell on a small area of a frame, the solar cell can only absorb a little solar energy. Accordingly, the solar cell of the conventional solar keyboard can only generate a little electric power. In other words, the conventional solar keyboard can only generate a little electric power for itself and cannot provide additional electric power for other electronic components of an electronic device equipped with the conventional solar keyboard.

### SUMMARY OF THE INVENTION

Therefore, an objective of the invention is to provide a solar keyboard utilizing large area to absorb much more solar energy and then convert the absorbed solar energy into electric power, so as to solve the aforesaid problems. Furthermore, the invention also provides an electronic device using the solar keyboard.

According to one embodiment, a solar keyboard of the invention comprises a base, a touch keyboard module and a solar cell. The touch keyboard module is disposed on the base and comprises a transparent layer. The solar cell is selectively disposed over or below the transparent layer. In this embodiment, an area of the solar cell is substantially equal to an area of the touch keyboard module.

According to another embodiment, an electronic device of the invention comprises a foundation and a display unit. The foundation comprises a base, a touch keyboard module, a solar cell and a power supply unit. The touch keyboard module is disposed on the base and comprises a transparent layer. The solar cell is selectively disposed over or below the transparent layer. In this embodiment, an area of the solar cell is substantially equal to an area of the touch keyboard module. The power supply unit is electrically connected to the solar cell. The display unit is pivotally connected to the foundation and electrically connected to the power supply unit.

According to another embodiment, a solar keyboard of the invention comprises a base, a plurality of keyswitches and a plurality of first solar cells. The keyswitches are disposed on the base and each of the first solar cells is disposed on one of the keyswitches. In this embodiment, an area of each solar cell is substantially equal to an area of the corresponding keyswitch. Furthermore, the solar keyboard of the invention may further comprise a frame and a second solar cell. The frame is disposed on the base, the keyswitches are disposed in the frame, and the second solar cell is disposed on the frame. An area of the second solar cell is substantially equal to an area of the frame.

According to another embodiment, an electronic device of the invention comprises a foundation and a display unit. The foundation comprises a base, a plurality of keyswitches, a plurality of first solar cells and a power supply unit. The keyswitches are disposed on the base and each of the first solar cells is disposed on one of the keyswitches. In this embodiment, an area of each solar cell is substantially equal to an area of the corresponding keyswitch. The power supply unit is electrically connected to the first solar cells. The display unit is pivotally connected to the foundation and electrically connected to the power supply unit. Furthermore, the foundation of the electronic device of the invention may further comprise a frame and a second solar cell. The frame is disposed on the base, the keyswitches are disposed in the frame, and the second solar cell is disposed on the frame. An area of the second solar cell is substantially equal to an area of the frame.

As mentioned in the above, since the area of the solar cell of the solar keyboard is substantially equal to the area of the touch keyboard module or real keyswitches, the solar keyboard of the invention can utilize much more area to absorb much more solar energy. Accordingly, the solar keyboard of the invention not only can generate electric power for itself but also can provide additional electric power for other electronic components of the electronic device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an electronic device according to one embodiment of the invention.

FIG. 2 is a functional block diagram illustrating the electronic device shown in FIG. 1.

FIG. 3 is a schematic diagram illustrating the solar keyboard shown in FIG. 1.

FIG. 4 is a schematic diagram illustrating a solar keyboard according to another embodiment of the invention.

FIG. 5 is a schematic diagram illustrating an electronic device according to another embodiment of the invention.

FIG. 6 is a functional block diagram illustrating the electronic device shown in FIG. 5.

FIG. 7 is a sectional view illustrating the keyswitch shown in FIG. 5.

FIG. 8 is a schematic diagram illustrating an electronic device according to another embodiment of the invention.

FIG. 9 is a functional block diagram illustrating the electronic device shown in FIG. 8.

### DETAILED DESCRIPTION

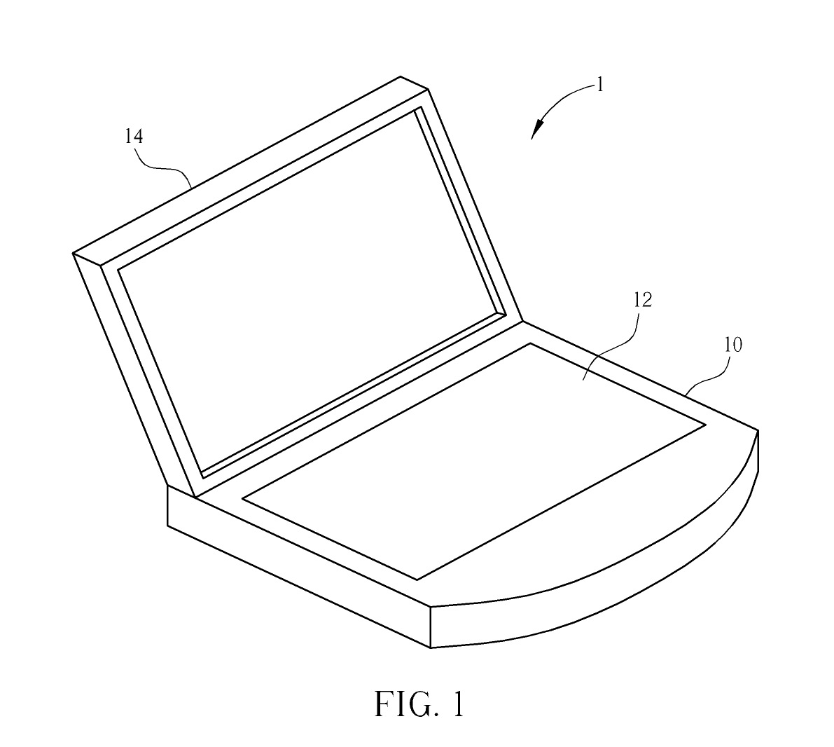

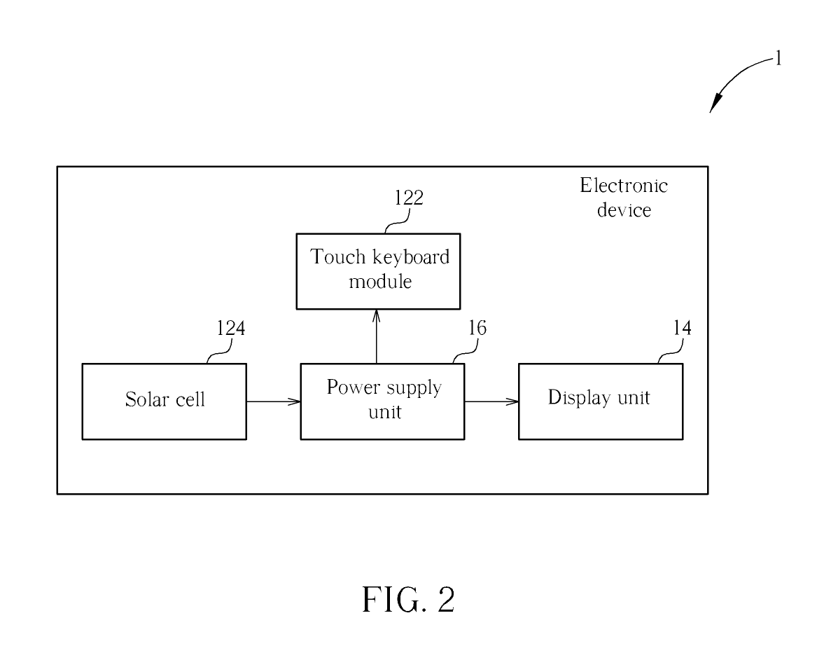

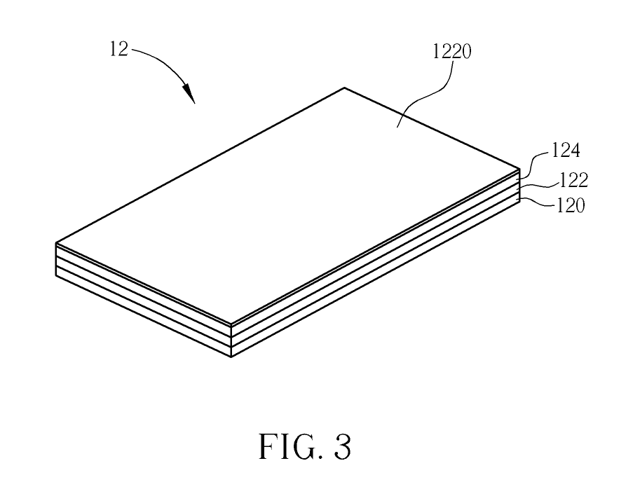

Referring to FIGS. 1 to 3, FIG. 1 is a schematic diagram illustrating an electronic device 1 according to one embodiment of the invention, FIG. 2 is a functional block diagram illustrating the electronic device 1 shown in FIG. 1, and FIG. 3 is a schematic diagram illustrating the solar keyboard 12 shown in FIG. 1. As shown in FIGS. 1 and 2, the electronic device 1 comprises a foundation 10, a solar keyboard 12, a display unit 14 and a power supply unit 16. The electronic device 1 may be a notebook or other electronic devices equipped with the solar keyboard 12. The display unit 14 may be a liquid crystal display device or other display devices. In this embodiment, the solar keyboard 12 is disposed on the foundation 10, the display unit 14 is pivotally connected to the foundation 10, and the power supply unit 16 is disposed in the foundation 10.

In general, the electronic device 1 may be equipped with some necessary hardware and software components for specific purposes, such as a Basic Input/Output System (BIOS), a Random Access Memory (RAM), a Read Only Memory (ROM), a main board (MB), a backlight module, an operating system (OS), etc., and it depends on practical applications. Functions of the aforesaid components are known for those skilled in the art, so it will not be depicted herein.

As shown in FIG. 3, the solar keyboard 12 comprises a base 120, a touch keyboard module 122 and a solar cell 124. As shown in FIG. 2, the power supply unit 16 is electrically connected to the touch keyboard module 122, the solar cell 124 and the display unit 14. In this embodiment, the touch keyboard module 122 may be a resistance touch keyboard module, a capacitance touch keyboard module, an optical touch keyboard module, a sonic touch keyboard module or other touch keyboard modules. The touch keyboard module 122 is disposed on the base 120. The touch keyboard module 122 comprises a transparent layer 1220. In practical applications, the transparent layer 1220 may be, but not limited to, a glass protective layer. In other words, the transparent layer 1220 is made of transparent material. In this embodiment, the solar cell 124 is disposed below the transparent layer 1220, so that the environmental light (e.g. sunlight) can pass through the transparent layer 1220 and then be absorbed by the solar cell 124. Accordingly, the solar cell 124 can convert the absorbed solar energy into electric power and then store the electric power in the power supply unit 16. Consequently, the power supply unit 16 can provide electric power for the touch keyboard module 122 or other electronic components (e.g. the display unit 14) of the electronic device 1.

In this embodiment, an area of the solar cell 124 is substantially equal to an area of the touch keyboard module 122, as shown in FIG. 3. Therefore, the solar keyboard 12 of the invention can increase the area for absorbing solar energy so as to generate much more electric power.

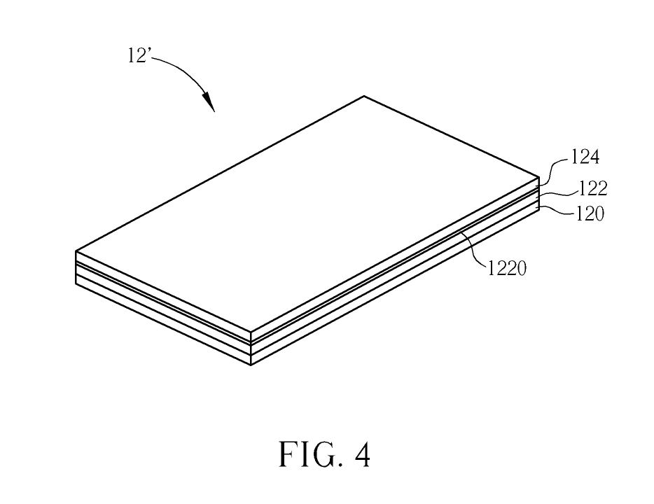

Referring to FIG. 4, FIG. 4 is a schematic diagram illustrating a solar keyboard 12′ according to another embodiment of the invention. The main difference between the solar keyboard 12′ and the aforesaid solar keyboard 12 is that the solar cell 124 of the solar keyboard 12′ is disposed over the transparent layer 1220, as shown in FIG. 4. Accordingly, the solar cell 124 can absorb the environmental light (e.g. sunlight) directly and then convert the absorbed solar energy into electric power. It should be noted that the same elements in FIG. 4 and FIG. 3 are represented by the same numerals, so the repeated explanation will not be depicted herein.

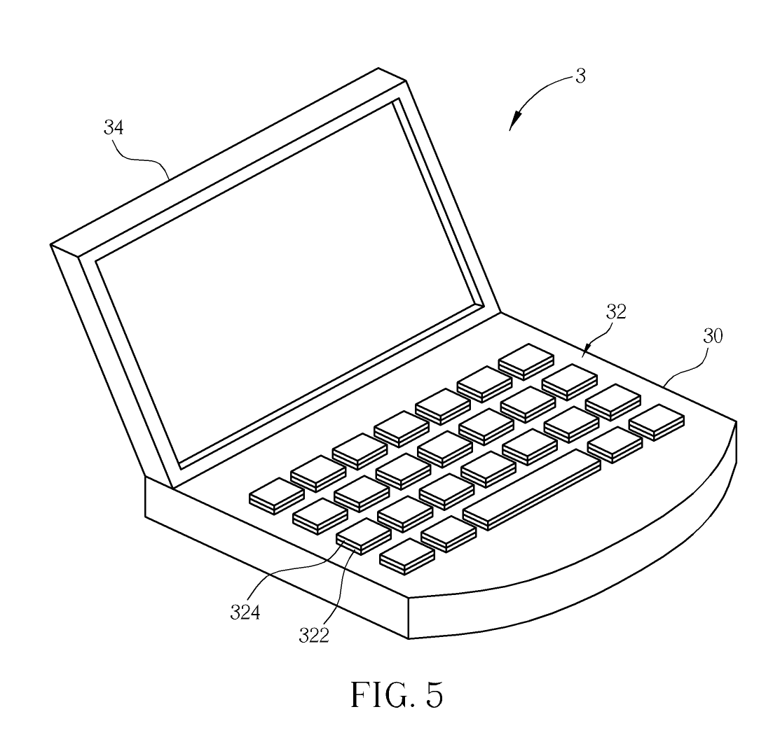

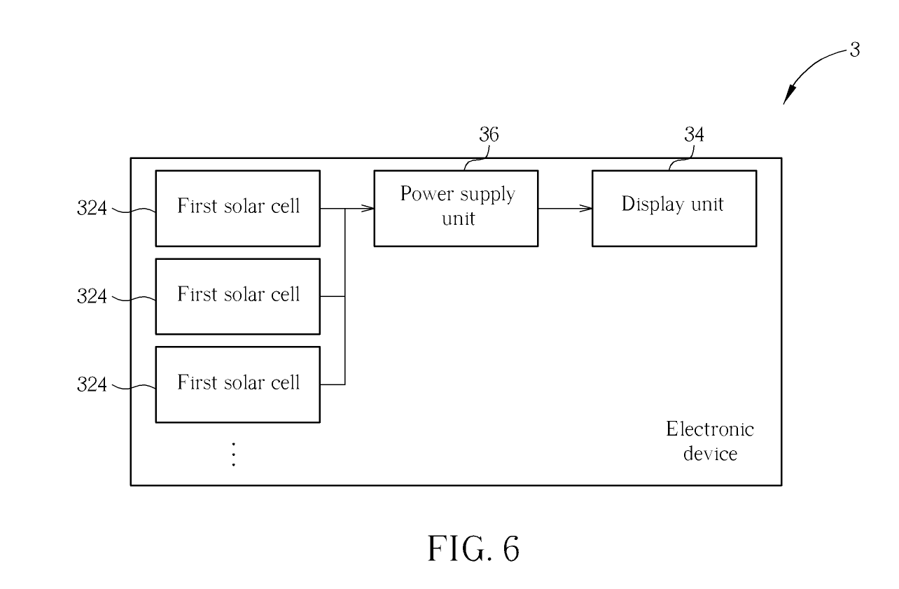

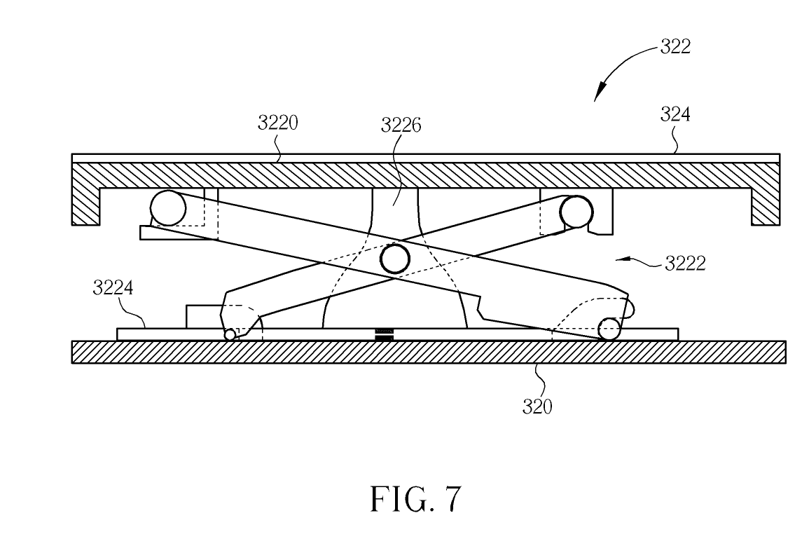

Referring to FIGS. 5 to 7, FIG. 5 is a schematic diagram illustrating an electronic device 3 according to another embodiment of the invention, FIG. 6 is a functional block diagram illustrating the electronic device 3 shown in FIG. 5, and FIG. 7 is a sectional view illustrating the keyswitch 322 shown in FIG. 5. As shown in FIGS. 5 and 6, the electronic device 3 comprises a foundation 30, a solar keyboard 32, a display unit 34 and a power supply unit 36. The electronic device 3 may be a notebook or other electronic devices equipped with the solar keyboard 32. The display unit 34 may be a liquid crystal display device or other display devices. In this embodiment, the solar keyboard 32 is disposed on the foundation 30, the display unit 34 is pivotally connected to the foundation 30, and the power supply unit 36 is disposed in the foundation 30.

As shown in FIG. 5, the solar keyboard comprises a plurality of keyswitches 322 and a plurality of first solar cells 324, wherein each of the first solar cells 324 is disposed on one of the keyswitches 322 correspondingly, and an area of each solar cell 324 is substantially equal to an area of the corresponding keyswitch 322. As shown in FIG. 6, the power supply unit 36 is electrically connected each of the first solar cells 324 and the display unit 34. As shown in FIG. 7, the keyswitch 322 is disposed on the base 320. Each of the keyswitches 322 comprises a key cap 3220, a lift support device 3222, a circuit board 3224 and a resilient member 3226. The lift support device 3222 and the resilient member 3226 are disposed between the key cap 3220 and the base 320, and the circuit board 3224 is disposed on the base 320. When the keyswitch 322 is pressed, the key cap 3220 will move toward the base 320 along with the lift support device 3222. In practical applications, the circuit board 3224 has a switch (e.g. a membrane switch or other switches) corresponding to the keyswitch 322. The resilient member 3226 may be, but not limited to, a rubber dome. The resilient member 3226 can provide elastic force for the key cap 3220 to move with respect to the base 320 upward or downward. When the keyswitch 322 is pressed, the resilient member 3226 will trigger the switch on the circuit board so as to execute function inputted by the user.

In this embodiment, the first solar cell 324 is disposed on the key cap 3220 of the keyswitch 322, so that the environmental light (e.g. sunlight) can be absorbed by the first solar cell 324. Accordingly, the first solar cells 324 can convert the absorbed solar energy into electric power and then store the electric power in the power supply unit 36. Consequently, the power supply unit 36 can provide electric power for other electronic components (e.g. the display unit 34) of the electronic device 3. Since the area of each solar cell 324 is substantially equal to the area of the corresponding keyswitch 322, the solar keyboard 32 of the invention can increase the area for absorbing solar energy so as to generate much more electric power.

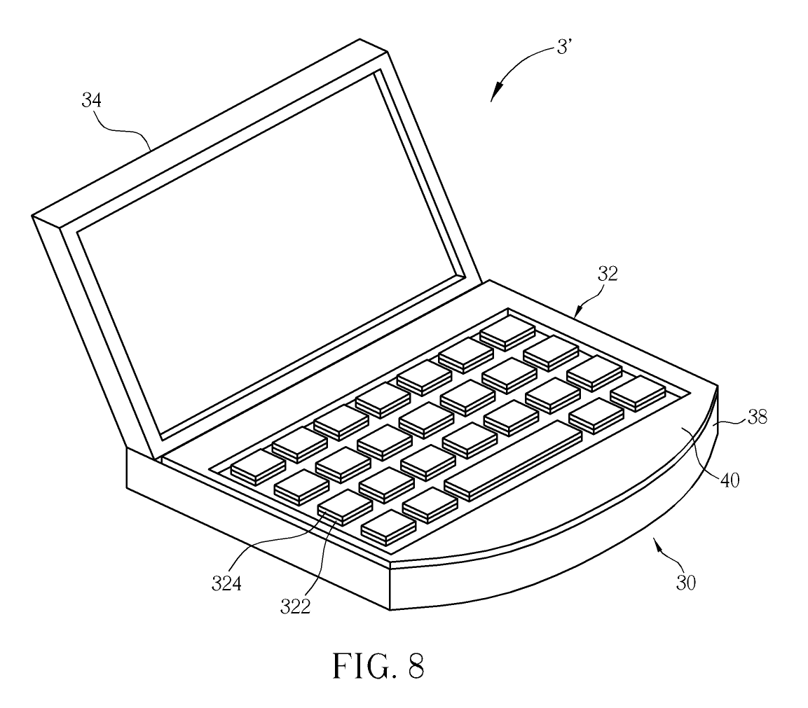

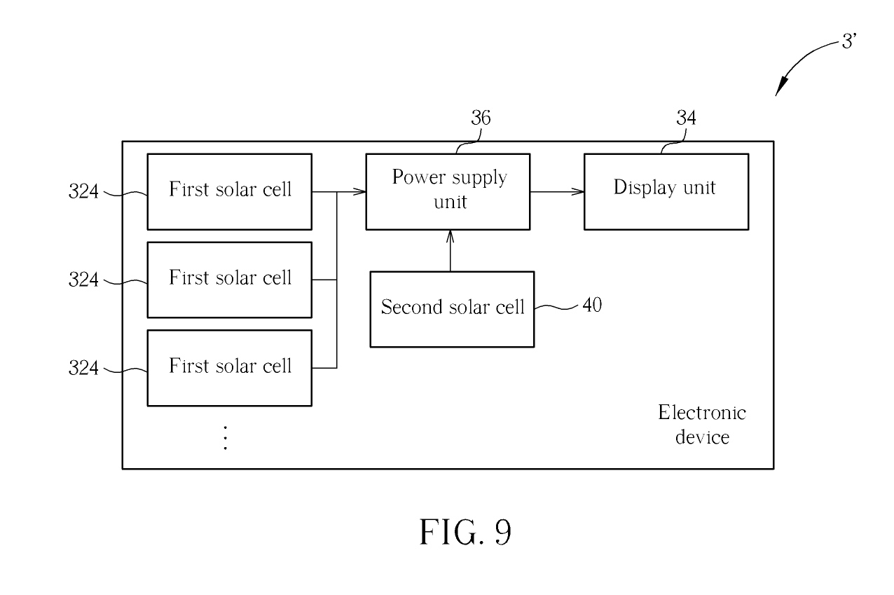

Referring to FIGS. 8 and 9, FIG. 8 is a schematic diagram illustrating an electronic device 3′ according to another embodiment of the invention and FIG. 9 is a functional block diagram illustrating the electronic device 3′ shown in FIG. 8. The main difference between the electronic device 3′ and the aforesaid electronic device 3 is that the electronic device 3′ further comprises a frame 38 and a second solar cell 40, as shown in FIG. 8. The frame 38 is disposed on the base (not shown in FIG. 8 and it can be referred to the base 320 shown in FIG. 7), each of the keyswitches 322 is disposed in the frame 38, and the second solar cell 40 is disposed on the frame 38. As shown in FIG. 9, the second solar cell 40 is also electrically connected to the power supply unit 36. In other words, the second solar cell 40 can also convert the absorbed solar energy into electric power and then store the electric power in the power supply unit 36. In this embodiment, an area of the second solar cell 40 is substantially equal to an area of the frame 38. Accordingly, the solar keyboard 32 of the invention can further increase the area for absorbing solar energy so as to generate much more electric power. It should be noted that the same elements in FIGS. 8-9 and FIGS. 5-6 are represented by the same numerals, so the repeated explanation will not be depicted herein.

Compared to the prior art, since the area of the solar cell of the solar keyboard is substantially equal to the area of the touch keyboard module or real keyswitches, the solar keyboard of the invention can utilize much more area to absorb much more solar energy. Accordingly, the solar keyboard of the invention not only can generate electric power for itself but also can provide additional electric power for other electronic components of the electronic device.

Those skilled in the art will readily observe that numerous modifications and alterations of the device and method may be made while retaining the teachings of the invention.

What is claimed is:

1. A solar keyboard comprising:
a base;
a touch keyboard module disposed on the base, the touch keyboard module comprising a transparent layer; and
a solar cell selectively disposed over or below the transparent layer, an area of the solar cell being substantially equal to an area of the touch keyboard module.

2. The solar keyboard of claim 1, wherein the touch keyboard module is one selected from a group consisting of: a resistance touch keyboard module, a capacitance touch keyboard module, an optical touch keyboard module and a sonic touch keyboard module.

3. The solar keyboard of claim 1, wherein the transparent layer is a glass protective layer.

4. An electronic device comprising:
a foundation comprising:
a base;
a touch keyboard module disposed on the base, the touch keyboard module comprising a transparent layer;
a solar cell selectively disposed over or below the transparent layer, an area of the solar cell being substantially equal to an area of the touch keyboard module;
a power supply unit electrically connected to the solar cell; and
a display unit pivotally connected to the foundation and electrically connected to the power supply unit.

5. The electronic device of claim 4, wherein the touch keyboard module is one selected from a group consisting of: a resistance touch keyboard module, a capacitance touch keyboard module, an optical touch keyboard module and a sonic touch keyboard module.

6. The electronic device of claim 4, wherein the transparent layer is a glass protective layer.

7. A solar keyboard comprising:
a base;
a plurality of keyswitches disposed on the base; and
a plurality of first solar cells, each of the first solar cells being disposed on one of the keyswitches, an area of each solar cell being substantially equal to an area of the corresponding keyswitch.

8. The solar keyboard of claim 7, further comprising a frame and a second solar cell, the frame being disposed on the base, the keyswitches being disposed in the frame, the second solar cell being disposed on the frame, an area of the second solar cell being substantially equal to an area of the frame.

9. An electronic device comprising:
a foundation comprising:
a base;
a plurality of keyswitches disposed on the base;
a plurality of first solar cells, each of the first solar cells being disposed on one of the keyswitches, an area of each solar cell being substantially equal to an area of the corresponding keyswitch;
a power supply unit electrically connected to the first solar cells; and
a display unit pivotally connected to the foundation and electrically connected to the power supply unit.

10. The electronic device of claim 9, wherein the foundation further comprises a frame and a second solar cell, the frame is disposed on the base, the keyswitches are disposed in the frame, the second solar cell is disposed on the frame and electrically connected to the power supply unit, an area of the second solar cell is substantially equal to an area of the frame.
